(19) United States
(12) Patent Application Publication
(10) Pub. No.: US 2019/0193523 A1
(43) Pub. Date: Jun. 27, 2019

(54) ELECTRIC VEHICLE

(71) Applicant: HONDA MOTOR CO., LTD., Tokyo (JP)

(72) Inventors: Yoshiyuki Takeuchi, Wako-shi (JP); Isao Tsunoda, Wako-shi (JP); Osamu Ishida, Wako-shi (JP); Nobumasa Toyoshima, Wako-shi (JP); Ryoma Taguchi, Tokyo (JP); Takahiro Ohmi, Tokyo (JP)

(21) Appl. No.: 16/218,516

(22) Filed: Dec. 13, 2018

(30) Foreign Application Priority Data
Dec. 21, 2017 (JP) 2017-245585

(51) Int. Cl. B60H 1/32; B60L 7/14; B60L 1/02; H02J 7/00; G01R 19/165

(52) U.S. Cl. CPC B60H 1/3208; B60L 7/14; B60L 1/02; B60L 3/0046; G01R 19/16542; H02J 2007/0037; H02J 7/0029

(57) ABSTRACT

An electric vehicle includes an electric motor, a power storage device, a control device, and a refrigerant circuit. The refrigerant circuit includes a compressor, an outdoor heat exchanger, an expansion valve, a first indoor heat exchanger, and a heating decompression valve. The heating decompression valve changes a passage resistance between the compressor and the outdoor heat exchanger. The control device increases the passage resistance by the heating decompression valve when the remaining capacity of the power storage device is equal to or larger than a predetermined value.

### CROSS-REFERENCE TO RELATED APPLICATION

Priority is claimed on Japanese Patent Application No. 2017-245585, filed Dec. 21, 2017, the content of which is incorporated herein by reference.

### BACKGROUND OF THE INVENTION

### Field of the Invention

The present invention relates to an electric vehicle.

### Description of Related Art

In electric vehicles, an electric motor functions as a generator at the time of braking the vehicle. That is, a rotation of a drive wheel is transmitted to an output shaft of the electric motor and electric power is regenerated by the electric motor in accordance with a rotation of the output shaft. A regenerated AC current is converted into a DC current by an inverter and the converted DC current is supplied from the inverter to a power storage device to be charged in the power storage device.

Among the electric vehicles, there is known an electric vehicle configured to limit a regeneration amount of the electric motor when a remaining capacity of the power storage device exceeds a predetermined value in order to protect the power storage device from overcharging. However, when the regeneration amount of the electric motor is limited, a regenerative braking force becomes weaker than that of a normal state and hence a passenger feels uncomfortable due to a change in brake feeling. Meanwhile, when the limitation of the regeneration amount during the braking operation is eliminated by prioritizing an effect of suppressing a change in brake feeling, a battery is deteriorated due to the overcharging.

As a countermeasure, there is disclosed a method of increasing electric power consumption of an electric load (hereinafter, referred to as a vehicle air conditioner) mounted on an electric vehicle when a remaining capacity of a power storage device exceeds a predetermined value at the time of generating a regenerative braking force.

Further, there is disclosed a method of simultaneously operating a cooling device for cooling a vehicle compartment and a heating device for heating the vehicle compartment when a remaining capacity of a power storage device exceeds a predetermined value during a regeneration of an electric motor (for example, see Japanese Unexamined Patent Application, First Publication No. 2015-162947 (hereinafter, referred to as Patent Literature 1)).

### SUMMARY OF THE INVENTION

In the vehicle air conditioner of Patent Literature 1, a cooling circuit and a heating circuit are completely separated from each other.

Meanwhile, among the electric vehicles, there is known an electric vehicle capable of cooling and heating the vehicle compartment using the vehicle air conditioner by providing a heat pump cycle in the vehicle air conditioner. However, in the electric vehicle, an operation of increasing the electric power consumption of the vehicle air conditioner when the remaining capacity of the power storage device exceeds a predetermined value during the regeneration of the electric motor is not disclosed.

Aspects of the present invention are contrived in view of the above-described circumstances and an object thereof is to provide an electric vehicle capable of increasing an electric power consumption of a vehicle air conditioner including a heat pump cycle when a remaining capacity of a power storage device exceeds a predetermined value during a regeneration of an electric motor.

In order to solve the above-described problems and achieve the object, the present invention adopts the following aspects.

(1) An electric vehicle according to an aspect of the present invention is an electric vehicle including an electric motor, a power storage device electrically connected to the electric motor, and a control device controlling the electric motor and the power storage device, including: a refrigerant circuit which includes a compressor compressing and discharging a sucked refrigerant, an outdoor heat exchanger exchanging heat with the compressed refrigerant, an expansion valve decompressing the refrigerant passing through the outdoor heat exchanger, and an indoor heat exchanger exchanging heat with the decompressed refrigerant and returning the refrigerant to the compressor, wherein the refrigerant circuit includes a resistance which is provided between the compressor and the outdoor heat exchanger to change a passage resistance of the compressed refrigerant, and wherein when a remaining capacity of the power storage device is equal to or larger than a predetermined value, the control device increases the passage resistance as compared with a case in which the remaining capacity of the power storage device is smaller than the predetermined value along with the operation of the compressor.

Here, a method of increasing the electric power consumption of the electric vehicle in order to protect the power storage device from overcharging at the time of charging the power storage device with the electric power regenerated by the electric motor will be described below as the waste electric power control.

According to Aspect (1), when the remaining capacity of the power storage device is equal to or larger than the predetermined value during the regeneration of the electric motor, the passage resistance is increased along with the operation of the compressor by the waste electric power control. Thus, since the passage resistance from the compressor to the outdoor heat exchanger increases as compared with a case before the waste electric power control, it is possible to decrease the efficiency of the cooling operation.

In this state, it is necessary to ensure the refrigerant circulation amount by increasing the output of the compressor to increase the discharge pressure of the compressor in order to obtain the cooling capacity before the waste electric power control. When the output of the compressor increases, it is possible to increase the electric power consumption of the compressor. In the waste electric power control, it is possible to prevent the overcharging of the power storage device when the electric power consumption of the compressor is larger than the electric power generated by the electric motor. Further, it is possible to decrease an increase speed of the remaining capacity of the power storage device when the electric power consumption of the compressor is smaller than the electric power generated by the electric motor.

(2) An electric vehicle according to an aspect of the present invention is an electric vehicle including an electric motor, a power storage device electrically connected to the electric motor, and a control device controlling the electric motor and the power storage device, including: a refrigerant circuit which includes a compressor compressing and discharging a sucked refrigerant, an outdoor heat exchanger exchanging heat with the compressed refrigerant, an expansion valve decompressing the refrigerant passing through the outdoor heat exchanger, and an indoor heat exchanger exchanging heat with the decompressed refrigerant and returning the refrigerant to the compressor, wherein when a remaining capacity of the power storage device is equal to or larger than a predetermined value, the control device decreases a passing air volume of a first air guide member controlling the passing air volume of the outdoor heat exchanger as compared with a case in which the remaining capacity of the power storage device is smaller than the predetermined value along with the operation of the compressor.

According to Aspect (2), when the remaining capacity of the power storage device is equal to or larger than the predetermined value during the regeneration of the electric motor, the passing air volume of the first air guide member is decreased to decrease the passing air volume of the outdoor heat exchanger along with the operation of the compressor by the waste electric power control. Thus, when the heat radiation amount of the outdoor heat exchanger is decreased to increase the temperature of the refrigerant (high pressure), it is possible to decrease the efficiency of the cooling operation.

In this state, it is necessary to increase the rotation speed due to an increase in compression work of the compressor or a decrease in volume efficiency in order to obtain the cooling capacity before the waste electric power control. Thus, it is possible to increase the electric power consumption of the compressor. In the waste electric power control, it is possible to prevent the overcharging of the power storage device when the electric power consumption of the compressor is larger than the electric power generated by the electric motor. Further, it is possible to decrease an increase speed of the remaining capacity of the power storage device when the electric power consumption of the compressor is smaller than the electric power generated by the electric motor.

(3) An electric vehicle according to an aspect of the present invention is an electric vehicle including an electric motor, a power storage device electrically connected to the electric motor, and a control device controlling the electric motor and the power storage device, including: a refrigerant circuit which includes a compressor compressing and discharging a sucked refrigerant, an outdoor heat exchanger exchanging heat with the compressed refrigerant, an expansion valve decompressing the refrigerant passing through the outdoor heat exchanger, and an indoor heat exchanger exchanging heat with the decompressed refrigerant and returning the refrigerant to the compressor, wherein when a remaining capacity of the power storage device is equal to or larger than a predetermined value, the control device decreases an opening degree of the expansion valve as compared with a case in which the remaining capacity of the power storage device is smaller than the predetermined value along with the operation of the compressor.

According to Aspect (3), when the remaining capacity of the power storage device is equal to or larger than the predetermined value during the regeneration of the electric motor, the opening degree of the expansion valve is decreased along with the operation of the compressor by the waste electric power control. Thus, it is possible to decrease the efficiency of the cooling operation by decreasing the refrigerant circulation amount as compared with a case before the waste electric power control.

In this state, it is necessary to ensure the refrigerant circulation amount by increasing the output of the compressor and increasing the discharge pressure of the refrigerant in order to obtain the cooling capacity before the waste electric power control. Since the output of the compressor increases, the electric power consumption of the compressor can be increased. In the waste electric power control, it is possible to prevent the overcharging of the power storage device when the electric power consumption of the compressor is larger than the electric power generated by the electric motor. Further, it is possible to decrease an increase speed of the remaining capacity of the power storage device when the electric power consumption of the compressor is smaller than the electric power generated by the electric motor.

(4) An electric vehicle according to an aspect of the present invention is an electric vehicle including an electric motor, a power storage device electrically connected to the electric motor, and a control device controlling the electric motor and the power storage device, including: a refrigerant circuit which includes a compressor compressing and discharging a sucked refrigerant, an outdoor heat exchanger exchanging heat with the compressed refrigerant, an expansion valve decompressing the refrigerant passing through the outdoor heat exchanger, and an indoor heat exchanger exchanging heat with the decompressed refrigerant and returning the refrigerant to the compressor, wherein the refrigerant circuit includes a second indoor heat exchanger which is disposed between the compressor and the outdoor heat exchanger to exchange heat with the compressed refrigerant, and wherein when the remaining capacity of the power storage device is equal to or larger than a predetermined value, the control device decreases a target temperature of the indoor heat exchanger as compared with a case in which the remaining capacity of the power storage device is smaller than the predetermined value and increases a target temperature of the second indoor heat exchanger as compared with the case in which the remaining capacity of the power storage device is smaller than the predetermined value along with the operation of the compressor.

According to Aspect (4), when the remaining capacity of the power storage device is equal to or larger than the predetermined value during the regeneration of the electric motor, the target temperature of the indoor heat exchanger is decreased and the target temperature of the second indoor heat exchanger is increased along with the operation of the compressor by the waste electric power control. When the target temperature of the indoor heat exchanger is decreased and the target temperature of the second indoor heat exchanger is increased, it is possible to decrease the operation efficiency of the vehicle air conditioner. Further, when the target temperature of the indoor heat exchanger is decreased and the target temperature of the second indoor heat exchanger is increased, it is possible to obtain the cooling capacity before the waste electric power control.

Thus, it is possible to increase the electric power consumption of the vehicle air conditioner in a state in which the cooling capacity before the waste electric power control is obtained. In the waste electric power control, it is possible to prevent the overcharging of the power storage device when the electric power consumption of the compressor is larger than the electric power generated by the electric motor. Further, it is possible to decrease an increase speed of the remaining capacity of the power storage device when the electric power consumption of the compressor is smaller than the electric power generated by the electric motor.

(5) The electric vehicle according to any one of Aspects (1) to (4) further includes: a switching member that is provided in the indoor heat exchanger to switch an introduction of air inside a vehicle compartment of the electric vehicle and air outside the vehicle compartment, wherein when the remaining capacity of the power storage device is equal to or larger than the predetermined value, the control device may switch the switching member so as to introduce the air outside the vehicle compartment.

In this way, when the remaining capacity of the power storage device is equal to or larger than the predetermined value during the regeneration of the electric motor, the air outside the vehicle compartment is selectively introduced along with the operation of the compressor by the waste electric power control. When the external air is introduced, it is possible to decrease the operation efficiency of the vehicle air conditioner. Thus, it is possible to increase the electric power consumption of the vehicle air conditioner in order to obtain the cooling capacity before the waste electric power control.

In the waste electric power control, it is possible to prevent the overcharging of the power storage device when the electric power consumption of the compressor is larger than the electric power generated by the electric motor. Further, it is possible to decrease an increase speed of the remaining capacity of the power storage device when the electric power consumption of the compressor is smaller than the electric power generated by the electric motor.

According to Aspects of the present invention, it is possible to increase the electric power consumption of the vehicle air conditioner including the heat pump cycle when the remaining capacity of the power storage device exceeds a predetermined value during the regeneration of the electric motor.

### BRIEF DESCRIPTION OF THE DRAWINGS

FIG. 1 is a configuration diagram of an electric vehicle including a vehicle air conditioner according to an embodiment of the present invention.

FIG. 2 is a configuration diagram illustrating a heating operation mode of the vehicle air conditioner according to the embodiment of the present invention.

FIG. 3 is a configuration diagram illustrating a cooling operation mode of the vehicle air conditioner according to the embodiment of the present invention.

FIG. 4 is a configuration diagram illustrating a dehumidifying heating operation mode of the vehicle air conditioner according to the embodiment of the present invention.

FIG. 5 is a configuration diagram illustrating a first waste electric power control of the electric vehicle according to the embodiment of the present invention.

FIG. 6 is a configuration diagram illustrating a second waste electric power control of the electric vehicle according to the embodiment of the present invention.

FIG. 7 is a graph calculating a regenerative electric power reduction amount using a grille shutter operation of the electric vehicle according to the embodiment of the present invention.

FIG. 8 is a configuration diagram illustrating a third waste electric power control of the electric vehicle according to the embodiment of the present invention.

FIG. 9 is a configuration diagram illustrating a fourth waste electric power control of the electric vehicle according to the embodiment of the present invention.

FIG. 10 is a configuration diagram illustrating a fifth waste electric power control of the electric vehicle according to the embodiment of the present invention.

FIG. 11 is a line diagram showing a relationship of electric power consumption with respect to a suction/discharge pressure difference of a compressor and an air side load (air conditioning load) of the electric vehicle according to the embodiment of the present invention.

### DETAILED DESCRIPTION OF THE INVENTION

An embodiment of the present invention will be described with reference to the drawings.

In the embodiment, a battery electric vehicle (BEV) is exemplified as an electric vehicle, but the present invention is not limited thereto. For example, other vehicles such as a hybrid vehicle (HV) and a fuel cell vehicle (FCV) may be used.

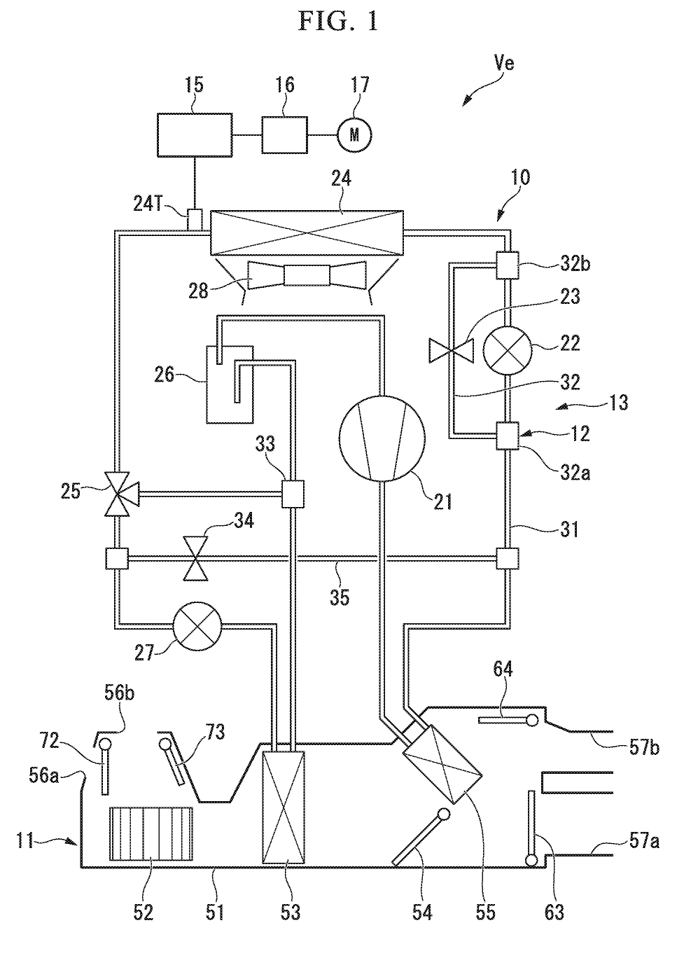

FIG. 1 is a configuration diagram of an electric vehicle Ve including a vehicle air conditioner 10.

As shown in FIG. 1, the vehicle air conditioner 10 is mounted on the electric vehicle Ve such as a battery electric vehicle which does not include an engine (an internal combustion engine) as a vehicle drive source. The electric vehicle Ve is a battery electric vehicle which includes a vehicle air conditioner 10, a control device (ECU: Electronic Control Unit) 15, a power storage device (a battery) 16, and an electric motor (a traveling motor) 17.

The electric motor 17 is electrically connected to the power storage device 16 through an inverter (not shown). At the time of driving the electric motor 17, a DC current output from the power storage device 16 is converted into an AC current by the inverter and is supplied to the electric motor 17. When the AC current is supplied to the electric motor 17, the electric motor 17 generates driving power. Since the electric motor 17 generates the driving power, a drive wheel is rotationally driven in a forward movement direction or a backward movement direction.

Meanwhile, the electric motor 17 serves as a generator at the time of braking the electric vehicle Ve. That is, the rotation of the drive wheel is transmitted to an output shaft of the electric motor 17 and electric power is regenerated by the electric motor 17 in accordance with the rotation of the output shaft. At this time, the electric motor 17 serves as a resistance and the resistance becomes a regenerative braking force to act on the electric vehicle Ve. The AC current which is regenerated by the electric motor 17 is converted into a DC current by the inverter. The converted DC current is supplied from the inverter to the power storage device 16 and is stored in the power storage device 16.

Further, the vehicle air conditioner 10 is mounted on the electric vehicle Ve. The vehicle air conditioner 10 mainly includes an air conditioning unit 11 and a heat pump cycle 12 through which a refrigerant can circulate.

The air conditioning unit 11 includes a duct 51 through which conditioned air flows, a switching member 59 that is accommodated in the duct 51, a blower 52, a first indoor heat exchanger (an indoor heat exchanger, an evaporator) 53, an air mix damper (a second air guide member) 54, and a second indoor heat exchanger (a heating heat exchanger, an indoor condenser) 55.

The duct 51 includes air inlets 56a and 56b and air outlets 57a and 57b.

Then, the blower 52, the first indoor heat exchanger 53, the air mix damper 54, and the second indoor heat exchanger 55 are disposed inside the duct 51. Further, these members 52, 53, 54, and 55 are disposed in this order from the upstream side (the side of the air inlets 56a and 56b) toward the downstream side (the side of the air outlets 57a and 57b) in the conditioned air flow direction of the duct 51.

The air inlets 56a and 56b respectively constitute an internal air inlet for taking internal air and an external air inlet for taking external air. The air inlets 56a and 56b are opened or closed by the switching member 59.

Hereinafter, the air inlet 56a will be described as the “internal air inlet 56a ” and the air inlet 56b will be described as the “external air inlet 56b”.

The switching member 59 includes an internal air door 72 and an external air door 73. The internal air door 72 opens or closes the internal air inlet 56a. The external air door 73 opens or closes the external air inlet 56b.

For example, the opening degrees of the internal air door 72 and the external air door 73 are adjusted by the control of a control device 15. When the opening degrees of the internal air door 72 and the external air door 73 are adjusted, the flow rate ratio of the internal air and the external air flowing into the duct 51 is adjusted.

That is, the switching member 59 is configured to switch the introduction of air inside the vehicle compartment of the electric vehicle Ve and air outside the vehicle compartment into the first indoor heat exchanger 53.

The air outlets 57a and 57b respectively constitute a VENT outlet and a DEF outlet. The air outlets 57a and 57b are respectively opened or closed by a VENT door 63 and a foot door 64. When the air outlets 57a and 57b are respectively opened or closed by the VENT door 63 and the foot door 64 by, for example, the control of the control device 15, a ratio of air blowing from the air outlets 57a and 57b is adjusted.

The blower 52 is driven by a motor in response to, for example, a driving voltage applied to the motor by the control of the control device 15. The blower 52 sends the conditioned air (at least one of the internal air and the external air) received from the air inlets 56a and 56b into the duct 51 toward the downstream side, that is, toward the first indoor heat exchanger 53 and the second indoor heat exchanger 55.

In the first indoor heat exchanger 53, the decompressed refrigerant flows thereinto so as to exchange heat between the low-pressure refrigerant flowing thereinto and the atmosphere inside the vehicle compartment (inside the duct 51). The first indoor heat exchanger 53 cools the conditioned air passing through the first indoor heat exchanger 53 by, for example, the heat absorbed when the refrigerant evaporates.

The refrigerant which exchanges heat in the first indoor heat exchanger 53 is returned to a compressor 21 through a gas-liquid separator 26.

The second indoor heat exchanger 55 is provided between the compressor 21 and an outdoor heat exchanger 24 (specifically, a heating decompression valve 22) in a refrigerant passage 31. The second indoor heat exchanger 55 can exchange heat with the refrigerant flowing thereinto and compressed at a high temperature and a high pressure. The second indoor heat exchanger 55 heats the conditioned air passing through the second indoor heat exchanger 55 by, for example, radiating heat.

The air mix damper 54 is rotated by, for example, the control of the control device 15. The air mix damper 54 rotates between a heating position of opening a ventilation path from the downstream side of the first indoor heat exchanger 53 toward the second indoor heat exchanger 55 inside the duct 51 and a cooling position of opening a ventilation path bypassing the second indoor heat exchanger 55. Accordingly, in the conditioned air passing through the first indoor heat exchanger 53, an air volume ratio between the volume of air introduced into the second indoor heat exchanger 55 and the volume of air bypassing the second indoor heat exchanger 55 and discharged into the vehicle compartment is adjusted.

The heat pump cycle 12 includes, for example, a compressor 21 which compresses the refrigerant, a heating decompression valve (a resistance) 22, a cooling electromagnetic valve 23, an outdoor heat exchanger 24, a three-way valve 25, a gas-liquid separator 26, and an expansion valve (a cooling decompression valve) 27 along with the first indoor heat exchanger 53 and the second indoor heat exchanger 55. The components constituting the heat pump cycle 12 are connected through the refrigerant passage 31. The refrigerant passage 31 is a passage through which the refrigerant can circulate.

The heat pump cycle 12, the first indoor heat exchanger 53, and the second indoor heat exchanger 55 constitute the refrigerant circuit 13. That is, the refrigerant circuit 13 is provided in the electric vehicle Ve.

The compressor 21 is connected between the gas-liquid separator 26 and the second indoor heat exchanger 55 and is operable to suck the refrigerant on the side of the gas-liquid separator 26 and to discharge the refrigerant to the second indoor heat exchanger 55. The compressor 21 is driven by a motor in response to, for example, a driving voltage applied to the motor by the control of the control device 15. The compressor 21 sucks a gas-phase refrigerant (a refrigerant gas) from the gas-liquid separator 26 and compresses the refrigerant so that the high-temperature and high-pressure refrigerant is discharged to the second indoor heat exchanger 55.

The heating decompression valve 22 and the cooling electromagnetic valve 23 are disposed in parallel at the downstream side of the second indoor heat exchanger 55 of the refrigerant passage 31.

The heating decompression valve 22 is, for example, a throttle valve which is provided between the compressor 21 and the outdoor heat exchanger 24 and can adjust an opening diameter of an opening portion. The heating decompression valve 22 is a resistance which can change a passage resistance of the refrigerant compressed inside the refrigerant passage 31 by adjusting the opening diameter of the opening portion.

Further, the heating decompression valve 22 decompresses and expands the refrigerant passing through the second indoor heat exchanger 55 and discharges the refrigerant to the outdoor heat exchanger 24 as a gas-liquid two-phase (a rich liquid-phase) atomized refrigerant at a low temperature and a low pressure.

The cooling electromagnetic valve 23 is provided on a bypass passage 32 which connects a first branch portion 32a and a second branch portion 32b provided at both sides of the heating decompression valve 22 on the refrigerant passage 31 and bypasses the heating decompression valve 22. The cooling electromagnetic valve 23 is opened or closed by, for example, the control of the control device 15. Furthermore, the cooling electromagnetic valve 23 is set to a closed state during the heating operation and is set to an open state during the cooling operation.

Accordingly, for example, the refrigerant which is discharged from the second indoor heat exchanger 55 is largely decompressed by the heating decompression valve 22 and flows into the outdoor heat exchanger 24 at a low temperature and a low pressure during the heating operation.

Meanwhile, the refrigerant which is discharged from the second indoor heat exchanger 55 passes through the cooling electromagnetic valve 23 and flows into the outdoor heat exchanger 24 in a high temperature state during the cooling operation.

The outdoor heat exchanger 24 is disposed outside the vehicle compartment and exchanges heat between the refrigerant flowing thereinto and the atmosphere outside the vehicle compartment. Further, an outlet temperature sensor 24T which detects the temperature (refrigerant outlet temperature Tout) of the refrigerant flowing out of the outlet of the outdoor heat exchanger 24 is provided at the downstream side of the outdoor heat exchanger 24. A signal indicating the refrigerant temperature detected by the outlet temperature sensor 24T is input to the control device 15. A signal input from the outlet temperature sensor 24T to the control device 15 is used to determine whether to perform various kinds of air conditioning control in the control device 15.

When the heating operation is performed, the outdoor heat exchanger 24 can absorb heat from the atmosphere outside the vehicle compartment by the low-temperature and low-pressure refrigerant flowing thereinto and increases the temperature of the refrigerant by absorbing heat from the atmosphere outside the vehicle compartment.

Meanwhile, when the cooling operation is performed, the outdoor heat exchanger 24 can radiate heat to the atmosphere outside the vehicle compartment by the high-temperature refrigerant flowing thereinto and cools the refrigerant by radiating heat to the atmosphere outside the vehicle compartment and blowing air using the first air guide member 28.

As the first air guide member 28, for example, a condenser fan which controls the volume of air passing through the outdoor heat exchanger 24 can be exemplified, but as the other examples, for example, a grille shutter or the like may be used. When the first air guide member 28 is the condenser fan, the condenser fan is driven in response to a driving voltage applied to a motor of the condenser fan by, for example, the control of the control device 15.

The three-way valve 25 discharges the refrigerant flowing out of the outdoor heat exchanger 24 by switching the gas-liquid separator 26 or an expansion valve 27. Specifically, the three-way valve 25 is connected to the outdoor heat exchanger 24, a merging portion 33 disposed on the side of the gas-liquid separator 26, and the expansion valve 27 and switches the refrigerant flow direction by, for example, the control of the control device 15.

When the heating operation is performed, the three-way valve 25 discharges the refrigerant passing through the outdoor heat exchanger 24 and flowing out of the outdoor heat exchanger 24 toward the merging portion 33 on the side of the gas-liquid separator 26.

Meanwhile, when the cooling operation is performed, the three-way valve 25 discharges the refrigerant passing through the outdoor heat exchanger 24 and flowing out of the outdoor heat exchanger 24 toward the expansion valve 27.

The gas-liquid separator 26 is connected between the compressor 21 and the merging portion 33 in the refrigerant passage 31 and is operable to separate the refrigerant flowing out of the merging portion 33 into a gas and a liquid and to suck the gas-phase refrigerant (the refrigerant gas) to the compressor 21.

The expansion valve 27 is a so-called throttle valve and is connected between the three-way valve 25 and the inlet of the first indoor heat exchanger 53. The expansion valve 27 decompresses and expands the refrigerant flowing out of the three-way valve 25, for example, in response to the valve opening degree controlled by the control device 15 and discharges the refrigerant to the first indoor heat exchanger 53 as a gas-liquid two-phase (a rich gas-phase) atomized refrigerant at a low temperature and a low pressure.

The first indoor heat exchanger 53 is connected between the expansion valve 27 and the merging portion 33 (the gas-liquid separator 26).

A dehumidifying electromagnetic valve 34 is provided in the dehumidifying passage 35. The dehumidifying passage 35 is connected to a portion of the first indoor heat exchanger 53 and a downstream portion of the three-way valve 25 in the refrigerant passage 31.

The dehumidifying electromagnetic valve 34 is controlled to be opened or closed by, for example, the control device 15. The dehumidifying electromagnetic valve 34 is set to an open state in the dehumidifying operation mode and is set to a closed state in the other operation modes (the cooling operation mode and the heating operation mode).

The control device 15 controls the air conditioning operation using the refrigerant in the air conditioning unit 11 and the heat pump cycle 12. The control device 15 controls the vehicle air conditioner 10 on the basis of an instruction signal input by an operator through a switch (not shown) or the like disposed inside the vehicle compartment. The control device 15 controls the electric motor 17 and the power storage device 16 and can switch the operation mode of the vehicle air conditioner 10 to the heating operation mode, the cooling operation mode, or the like.

Information on SOC (State Of Charge) corresponding to a charging rate of the power storage device 16 or chargeable electric power calculated on the basis of the SOC is input to the control device 15. The chargeable electric power is electric power which is chargeable to the power storage device 16. In order to prevent overcharging of the power storage device 16, the chargeable electric power can be obtained from, for example, a table in which the chargeable electric power decreases with an increase in SOC and an upper limit value is set to 0.

Further, the control device 15 determines whether the remaining capacity of the power storage device 16 is equal to or larger than a predetermined value on the basis of the chargeable electric power. Furthermore, information on the regenerative electric power input to the power storage device 16 is input to the control device 15.

Further, the control device 15 has a function through which it is capable of controlling the electric motor 17, the vehicle air conditioner 10, the compressor 21, and the first air guide member (fan) 28. For example, at the time of the regeneration of the cooling operation mode, the control device 15 can selectively control the heating decompression valve 22, the cooling electromagnetic valve 23, the expansion valve 27, the first air guide member 28, and the air mix damper 54 along with the operation of the compressor 21 when the remaining capacity of the power storage device 16 is equal to or larger than the predetermined value.

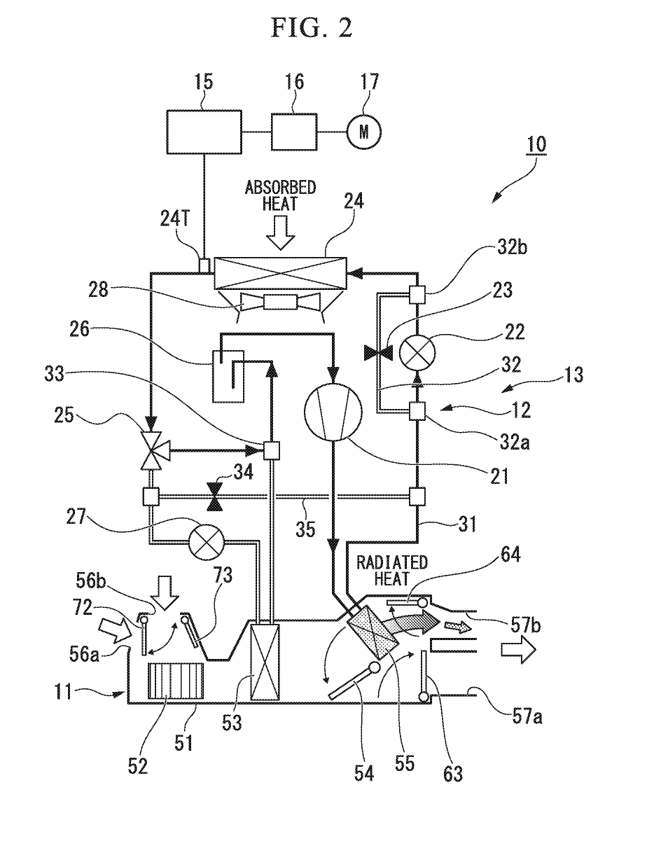

Next, the operations of the vehicle air conditioner 10 in the heating operation mode, the cooling operation mode, and the dehumidifying operation mode will be described with reference to FIGS. 2 to 4. First, the heating operation mode of the vehicle air conditioner 10 will be described with reference to FIG. 2.

(Heating Operation Mode)

As shown in FIG. 2, when the heating operation is performed by the vehicle air conditioner 10, the air mix damper 54 is set to the heating position for opening the ventilation path toward the second indoor heat exchanger 55. Further, the cooling electromagnetic valve 23 is set to a closed state and the three-way valve 25 is set to a state in which the outdoor heat exchanger 24 and the merging portion 33 are connected. Furthermore, in the example of FIG. 2, in the air conditioning unit 11, the foot door 64 is set to an open state and the VENT door 63 is set to a closed state. However, these doors can be arbitrarily opened or closed by the operation of the operator.

In this case, in the heat pump cycle 12, the high-temperature and high-pressure refrigerant discharged from the compressor 21 heats the conditioned air inside the duct 51 of the air conditioning unit 11 by the heat radiated in the second indoor heat exchanger 55.

The refrigerant passing through the second indoor heat exchanger 55 is expanded (decompressed) by the heating decompression valve 22 to become a rich liquid-phase atomized refrigerant and then exchanges heat in the outdoor heat exchanger 24 (absorbs heat from the atmosphere outside the vehicle compartment) to become a rich gas-phase atomized refrigerant. The refrigerant passing through the outdoor heat exchanger 24 passes through the three-way valve 25 and the merging portion 33 and flows into the gas-liquid separator 26. Then, the refrigerant flowing into the gas-liquid separator 26 is separated into a gas phase and a liquid phase and the gas-phase refrigerant is sucked into the compressor 21.

In this way, when the blower 52 of the air conditioning unit 11 is driven in a state in which the refrigerant flows inside the refrigerant passage 31 of the heat pump cycle 12, the conditioned air flows inside the duct 51 of the air conditioning unit 11. The conditioned air flowing inside the duct 51 passes through the first indoor heat exchanger 53 and then passes through the second indoor heat exchanger 55.

Then, the conditioned air exchanges heat with the second indoor heat exchanger 55 when passing through the second indoor heat exchanger 55 and is supplied into the vehicle compartment through the air outlet 57b for a heating purpose.

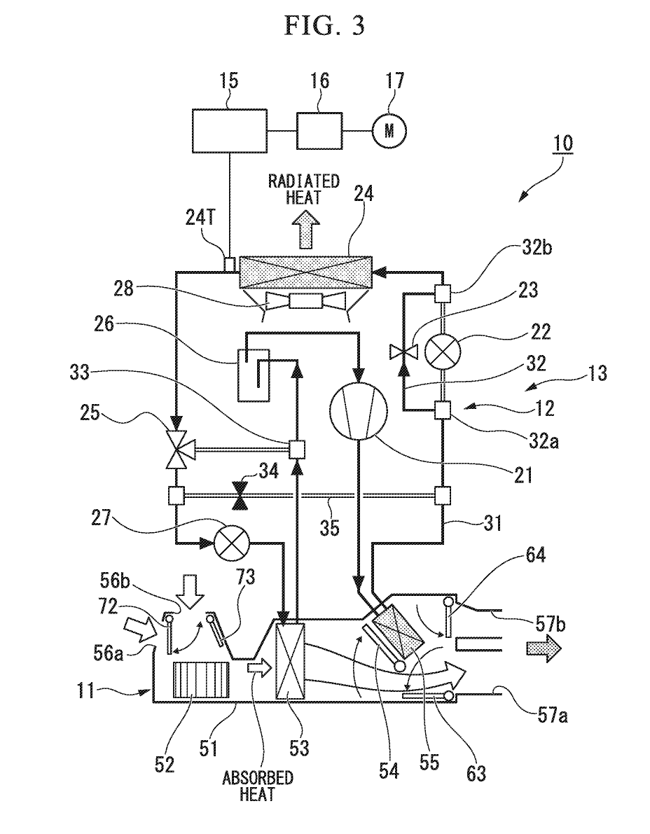

Next, the cooling operation mode of the vehicle air conditioner 10 will be described with reference to FIG. 3.

(Cooling Operation Mode)

As shown in FIG. 3, when the cooling operation is performed by the vehicle air conditioner 10, the air mix damper 54 is set to the cooling position so that the conditioned air passing through the first indoor heat exchanger 53 bypasses the second indoor heat exchanger 55. Further, the cooling electromagnetic valve 23 is set to an open state (the heating decompression valve 22 is set to a closed state) and the three-way valve 25 is set to a state in which the outdoor heat exchanger 24 and the expansion valve 27 are connected. Furthermore, in the example of FIG. 3, in the air conditioning unit 11, the foot door 64 is set to a closed state and the VENT door 63 is set to an open state. However, these doors can be arbitrarily opened or closed by the operation of the operator.

In this case, in the heat pump cycle 12, the high-temperature and high-pressure refrigerant discharged from the compressor 21 passes through the second indoor heat exchanger 55 and the cooling electromagnetic valve 23, radiates heat to the atmosphere outside the vehicle compartment in the outdoor heat exchanger 24, and then flows into the expansion valve 27. At this time, the refrigerant is expanded by the expansion valve 27 to become a rich liquid-phase atomized refrigerant and then absorbs heat in the first indoor heat exchanger 53 to cool the conditioned air inside the duct 51 of the air conditioning unit 11.

A rich gas-phase refrigerant passing through the first indoor heat exchanger 53 passes through the merging portion 33 and flows into the gas-liquid separator 26 to be separated into a gas phase and a liquid phase by the gas-liquid separator 26. Then, the gas-phase refrigerant is sucked into the compressor 21.

In this way, when the blower 52 of the air conditioning unit 11 is driven while the refrigerant flows inside the refrigerant passage 31, the conditioned air flows inside the duct 51 of the air conditioning unit 11 and exchanges heat with the first indoor heat exchanger 53 when the conditioned air passes through the first indoor heat exchanger 53. Then, the conditioned air bypasses the second indoor heat exchanger 55 and is supplied into the vehicle compartment through the VENT outlet (that is, the air outlet) 57a for the purpose of cooling.

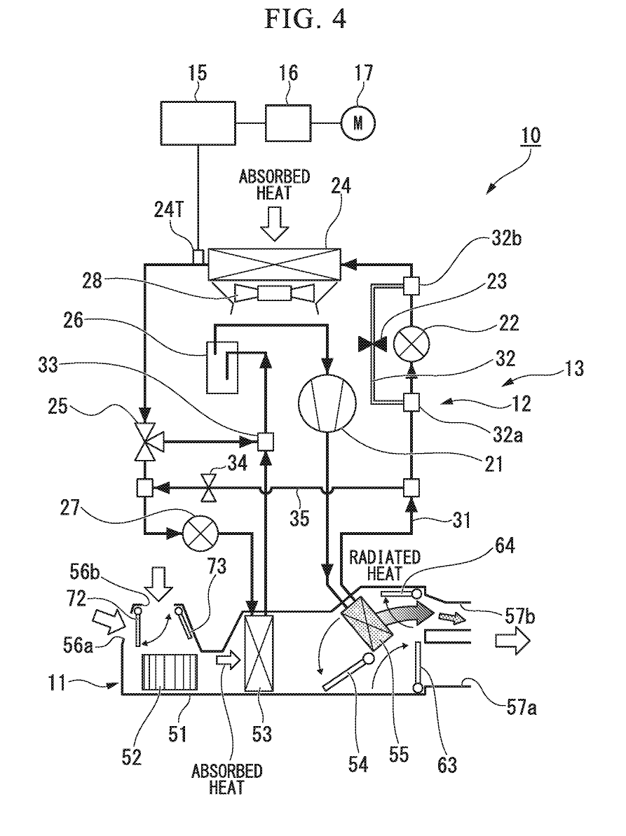

Next, the dehumidifying heating operation mode of the vehicle air conditioner 10 will be described with reference to FIG. 4.

(Dehumidifying Heating Operation Mode)

As shown in FIG. 4, when the cooling operation is performed by the vehicle air conditioner 10, the second air guide member 54 is set to the heating position in which the conditioned air passing through the first indoor heat exchanger 53 passes through a heating path and the dehumidifying electromagnetic valve 34 is set to an open state. Further, the cooling electromagnetic valve 23 is set to a closed state.

In this case, in the heat pump cycle 12, the high-temperature and high-pressure refrigerant discharged from the compressor 21 heats the conditioned air inside the duct 51 by the heat radiated in the second indoor heat exchanger 55. In the refrigerant passing through the second indoor heat exchanger 55, one refrigerant flows toward the outdoor heat exchanger 24 and the other refrigerant flows into the dehumidifying passage 35.

Specifically, similarly to the heating operation, one refrigerant is expanded by the heating decompression valve 22 and absorbs heat from the outdoor atmosphere in the outdoor heat exchanger 24.

Further, the other refrigerant is guided to the expansion valve 27 through the dehumidifying passage 35, is expanded by the expansion valve 27, and absorbs heat in the first indoor heat exchanger 53.

One refrigerant and the other refrigerant are merged in the merging portion 33 and flow into the gas-liquid separator 26 so that only the gas-phase refrigerant is sucked into the compressor 21.

Further, the conditioned air flowing inside the duct 51 is cooled when passing through the first indoor heat exchanger 53. At this time, the conditioned air passing through the first indoor heat exchanger 53 is dehumidified while being cooled to a dew point or less. Subsequently, the dehumidified conditioned air passes through the heating path and is supplied into the vehicle compartment through the air outlet 57b for the purpose of dehumidifying and heating.

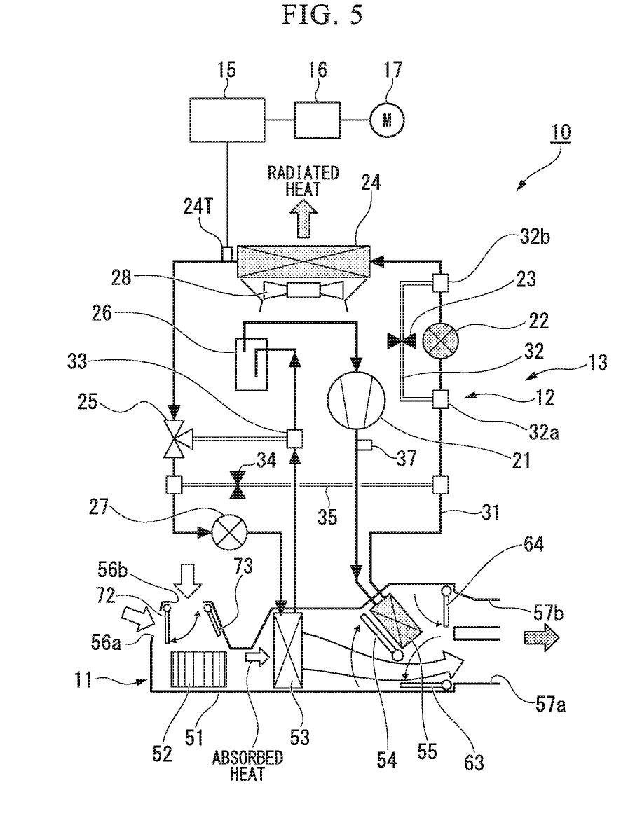

Next, an example of performing the waste electric power control so that the remaining capacity of the power storage device 16 does not exceed a predetermined value at the time of storing the regenerative electric power in the power storage device 16 in the cooling operation mode, the dehumidifying heating operation mode, or the like of the vehicle air conditioner 10 will be described with reference to FIGS. 5 to 11 and Tables 1 and 2.

First, first to fifth waste electric power control can be exemplified as the waste electric power control of the vehicle air conditioner 10 in the cooling operation mode. Hereinafter, the first to fifth waste electric power control will be sequentially described.

An example of increasing the electric power consumption of the vehicle air conditioner 10 by closing the cooling electromagnetic valve 23 of the vehicle air conditioner 10 and throttling the heating decompression valve 22 will be described with reference to FIG. 5 as the first waste electric power control.

(First Waste Electric Power Control)

As shown in FIG. 5, when the remaining capacity of the power storage device 16 is equal to or larger than a predetermined value, the control device 15 increases the passage resistance of the heating decompression valve 22 as compared with a case in which the remaining capacity of the power storage device 16 is smaller than the predetermined value by closing the cooling electromagnetic valve 23 along with the operation of the compressor 21.

In the first waste electric power control, when the remaining capacity of the power storage device 16 is equal to or larger than the predetermined value during the operation of the compressor 21, the heating decompression valve 22 is throttled to increase the passage resistance. Thus, since the passage resistance from the compressor 21 to the outdoor heat exchanger 24 increases and the pressure loss (friction loss) increases as compared with a case before the waste electric power control, the refrigerant circulation amount inside the refrigerant passage 31 can be decreased. That is, it is possible to decrease the efficiency of the cooling operation or the dehumidifying cooling operation of the vehicle air conditioner 10.

In this state, it is necessary to increase the refrigerant flow rate by increasing the rotation speed of the compressor 21 in order to obtain the cooling capacity before the waste electric power control. Since the rotation speed of the compressor 21 increases, the electric power consumption of the compressor 21 increases so that the waste electric power amount of the vehicle air conditioner 10 can be ensured.

Accordingly, in the first waste electric power control, it is possible to prevent the overcharging of the power storage device 16 when the electric power consumption of the compressor 21 is larger than the electric power generated by the electric motor 17. Further, it is possible to decrease an increase speed of the remaining capacity of the power storage device 16 when the electric power consumption of the compressor 21 is smaller than the electric power generated by the electric motor 17.

For example, the compressor 21 is controlled by using information of a temperature sensor or the like provided in the first indoor heat exchanger 53 so that the temperature of the first indoor heat exchanger 53 becomes a target value.

The heating decompression valve 22 can be throttled in response to a required waste electric power amount within the upper limit of the discharge pressure of the compressor 21. The target value of the discharge pressure sensor 37 is set in response to a required waste electric power amount.

The workload (the electric power consumption) of the compressor 21 increases due to an increase in compression work, an increase in required flow rate of the refrigerant with an increase in outlet enthalpy of the outdoor heat exchanger 24, and an increase in rotation speed with a decrease in volume efficiency. At this time, since the temperature of the second indoor heat exchanger 55 increases, for example, the opening degree of the air mix damper 54 is made smaller in order to set the temperature (heat radiation quantity) of air blown out from the air outlet 57a as a target value. The increased electric power work is mainly discharged as thermal energy from the outdoor heat exchanger 24. Furthermore, in the case of the dehumidifying cooling operation, the opening degree of the air mix damper 54 is larger than that of the cooling operation and becomes an intermediate opening degree between a fully closed state and a fully open state (not shown).

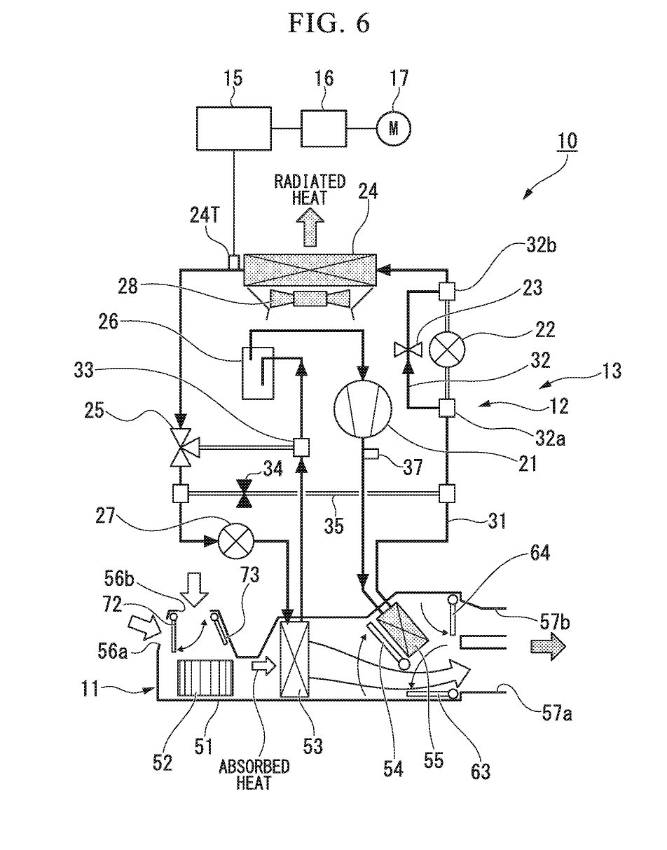

Next, an example of increasing the electric power consumption of the vehicle air conditioner 10 by controlling the first air guide member 28 while opening the cooling electromagnetic valve 23 of the vehicle air conditioner 10 will be described with reference to FIG. 6 as the second waste electric power control.

(Second Waste Electric Power Control)

As shown in FIG. 6, when the remaining capacity of the power storage device 16 is equal to or larger than a predetermined value, the control device opens the cooling electromagnetic valve 23 along with the operation of the compressor 21. Further, the passing air volume of the first air guide member 28 controlling the passing air volume of the outdoor heat exchanger 24 is controlled to be smaller than that of a case in which the remaining capacity of the power storage device 16 is smaller than the predetermined value.

That is, when the first air guide member 28 is a condenser fan, the rotation speed of the fan is decreased or stopped to decrease the passing air volume of the first air guide member 28.

In this case, for example, the first air guide member 28 can be decreased in speed in response to the required waste electric power amount within the upper limit of the discharge pressure of the compressor 21. The target value of the discharge pressure sensor 37 is set in response to the required waste electric power amount.

Further, when the first air guide member 28 is a grille shutter, a gap of the grille shutter is narrowed or the grille shutter is closed to decrease the passing air volume of the first air guide member 28.

Here, since the air resistance of the traveling vehicle decreases when the grille shutter is closed, there is concern of discomfort in the brake feeling since the vehicle speed increases even when the waste electric power amount increases.

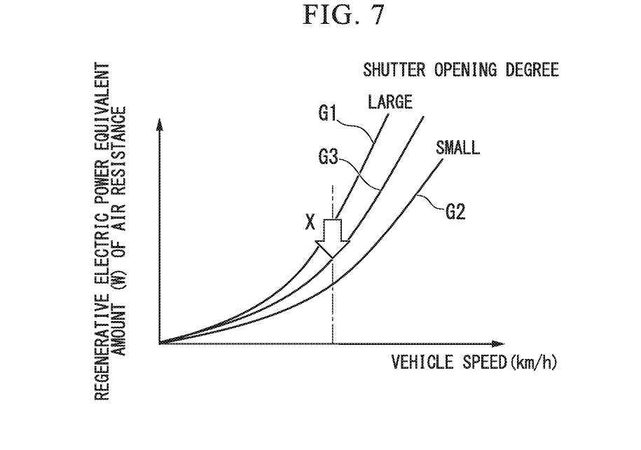

Therefore, in order to obtain the vehicle speed reduction feeling as in the case before the operation of the grille shutter, the grille shutter operation is determined by the following condition. That is, when a relationship of (the possible waste electric power due to the second waste electric power control)>(the regenerative electric power reduction amount due to the grille shutter operation) is established while (the discharge pressure of the discharge pressure sensor 37)<(the upper-limit discharge pressure of the compressor 21), the regenerative electric power reduction amount X due to the grille shutter operation is calculated by the characteristic of the graph of FIG. 7.

In the graph of FIG. 7, a vertical axis indicates a regenerative electric power equivalent amount (W) of the air resistance. The “regenerative electric power equivalent amount (W) of the air resistance” indicates the regenerative electric power when regeneration gives the same amount of resistance as the air resistance. A horizontal axis indicates a vehicle speed (km/h). Graphs G1 to G3 indicate the opening degree of the grille shutter.

When the passing air volume of the first air guide member 28 is decreased, the passing air volume of the outdoor heat exchanger 24 is decreased and hence the heat radiation amount of the outdoor heat exchanger 24 can be decreased.

Here, the refrigerant passing through the cooling electromagnetic valve 23 flows into the outdoor heat exchanger 24 at a high pressure and a high temperature. Thus, since the heat radiation amount of the outdoor heat exchanger 24 decreases, the high temperature and the high pressure of the refrigerant increase. Thus, it is possible to decrease the efficiency of the cooling operation or the dehumidifying cooling operation of the vehicle air conditioner 10.

In this state, it is necessary to increase the refrigerant flow rate by increasing the rotation speed of the compressor 21 in order to obtain the cooling capacity before the waste electric power control. Since the rotation speed of the compressor 21 increases, the electric power consumption of the compressor 21 increases so that the waste electric power amount of the vehicle air conditioner 10 can be ensured.

Accordingly, in the second waste electric power control, it is possible to prevent the overcharging of the power storage device 16 when the electric power consumption of the compressor 21 is larger than the electric power generated by the electric motor 17. Further, it is possible to decrease an increase speed of the remaining capacity of the power storage device 16 when the electric power consumption of the compressor 21 is smaller than the electric power generated by the electric motor 17.

For example, the compressor 21 is controlled by using information of a temperature sensor or the like provided in the first indoor heat exchanger 53 so that the temperature of the first indoor heat exchanger 53 becomes the target value.

The workload (the electric power consumption) of the compressor 21 increases due to an increase in compression work, an increase in required flow rate of the refrigerant with an increase in outlet enthalpy of the outdoor heat exchanger 24, and an increase in rotation speed with a decrease in volume efficiency. At this time, since the temperature of the second indoor heat exchanger 55 increases, for example, the opening degree of the air mix damper 54 is made smaller in order to set the temperature (heat radiation quantity) of air blown out from the air outlet 57a as a target value. The increased electric power work is mainly discharged as thermal energy from the outdoor heat exchanger 24. Furthermore, in the case of the dehumidifying cooling operation, the opening degree of the air mix damper 54 is larger than that of the cooling operation and becomes an intermediate opening degree between a fully closed state and a fully open state (not shown).

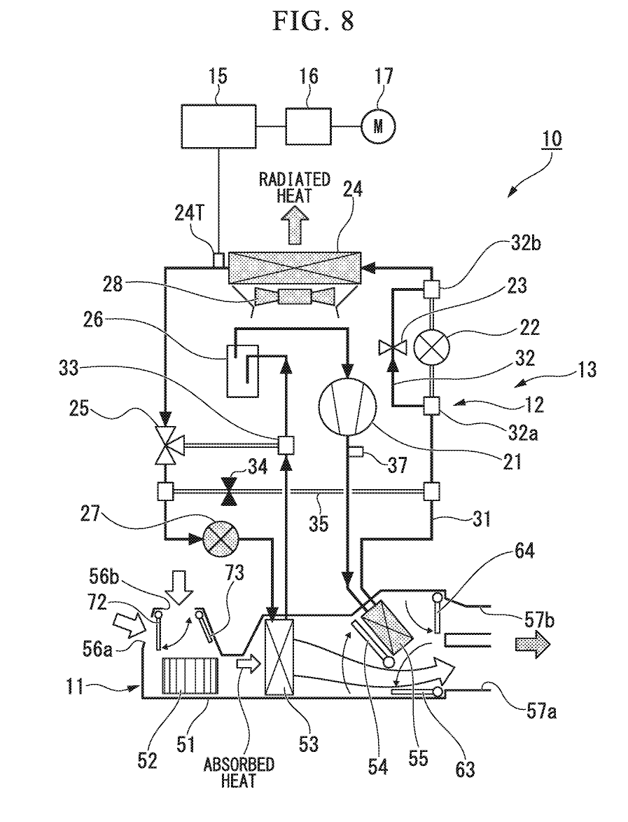

Next, an example of increasing the electric power consumption of the vehicle air conditioner 10 by decreasing the opening degree of the expansion valve 27 while opening the cooling electromagnetic valve 23 of the vehicle air conditioner 10 will be described with reference to FIG. 8 as the third waste electric power control.

(Third Waste Electric Power Control)

As shown in FIG. 8, when the remaining capacity of the power storage device 16 is a predetermined value or more, the control device 15 throttles the expansion valve 27 along with the operation of the compressor 21. Since the expansion valve 27 is throttled, the opening degree of the expansion valve 27 is decreased as compared with a case in which the remaining capacity of the power storage device 16 is smaller than the predetermined value.

In the third waste electric power control, when the remaining capacity of the power storage device 16 is equal to or larger than the predetermined value during the operation of the compressor 21, the opening degree of the expansion valve 27 is decreased. Thus, it is possible to decrease the refrigerant circulation amount inside the refrigerant passage 31 from the compressor 21 to the outdoor heat exchanger 24 as compared with a case before the waste electric power control. That is, it is possible to decrease the efficiency of the cooling operation or the dehumidifying cooling operation of the vehicle air conditioner 10.

In this state, it is necessary to increase the refrigerant flow rate by increasing the rotation speed of the compressor 21 in order to obtain the cooling capacity before the waste electric power control. Since the rotation speed of the compressor 21 increases, it is possible to ensure the waste electric power amount of the vehicle air conditioner 10 by increasing the electric power consumption of the compressor 21.

Accordingly, in the third waste electric power control, it is possible to prevent the overcharging of the power storage device 16 when the electric power consumption of the compressor 21 is larger than the electric power generated by the electric motor 17. Further, it is possible to decrease an increase speed of the remaining capacity of the power storage device 16 when the electric power consumption of the compressor 21 is smaller than the electric power generated by the electric motor 17.

For example, the compressor 21 is controlled by using information of a temperature sensor or the like provided in the first indoor heat exchanger 53 so that the temperature of the first indoor heat exchanger 53 becomes the target value.

The opening degree of the expansion valve 27 can be decreased in response to the required waste electric power amount within the upper limit of the discharge pressure of the compressor 21. The target value of the discharge pressure sensor 37 is set in response to the required waste electric power amount.

The workload (the electric power consumption) of the compressor 21 increases due to an increase in compression work, an increase in required flow rate of the refrigerant with an increase in outlet enthalpy of the outdoor heat exchanger 24, and an increase in rotation speed with a decrease in volume efficiency. At this time, since the temperature of the second indoor heat exchanger 55 increases, for example, the opening degree of the air mix damper 54 is made smaller in order to set the temperature (heat radiation quantity) of air blown out from the air outlet 57a as a target value. The increased electric power work is mainly discharged as thermal energy from the outdoor heat exchanger 24. Furthermore, in the case of the dehumidifying cooling operation, the opening degree of the air mix damper 54 is larger than that of the cooling operation and becomes an intermediate opening degree between a fully closed state and a fully open state (not shown).

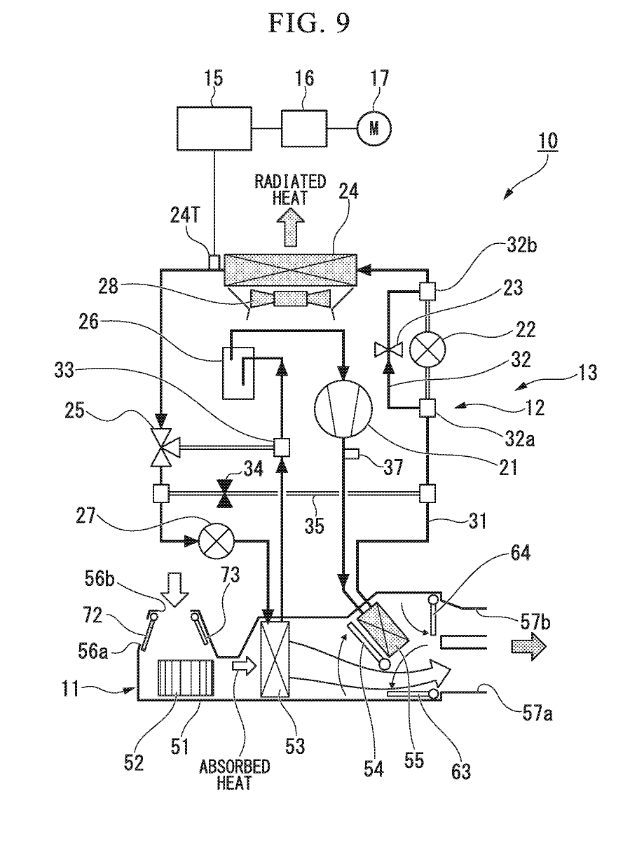

Further, an example of increasing the electric power consumption of the vehicle air conditioner 10 by switching the switching member 59 of the vehicle air conditioner 10 to introduce air outside the vehicle compartment will be described with reference to FIG. 9 as the fourth waste electric power control.

(Fourth Waste Electric Power Control)

As shown in FIG. 9, when the remaining capacity of the power storage device 16 is equal to or larger than a predetermined value, the control device 15 switches the switching member 59 to introduce air outside the vehicle compartment.

For example, the internal air inlet 56a is switched to a closed state by the internal air door 72 of the switching member 59 and the external air inlet 56b is switched to an open state by the external air door 73. Thus, the high-temperature air (that is, the external air) 75 outside the vehicle compartment can be introduced from the external air inlet 56b into the duct 51. Since the high-temperature external air 75 is introduced into the duct 51, the operation efficiency of the vehicle air conditioner 10 can be decreased.

In this state, it is possible to increase the electric power consumption by increasing the cooling work of the vehicle air conditioner 10 in order to obtain the cooling capacity before the waste electric power control.

Accordingly, in the fourth waste electric power control, it is possible to prevent the overcharging of the power storage device 16 when the electric power consumption of the compressor 21 is larger than the electric power generated by the electric motor 17. Further, it is possible to decrease an increase speed of the remaining capacity of the power storage device 16 when the electric power consumption of the compressor 21 is smaller than the electric power generated by the electric motor 17.

Furthermore, the fourth waste electric power control may be not only the cooling operation but also the dehumidifying cooling operation. In the case of the dehumidifying cooling operation, the opening degree of the air mix damper 54 is larger than that of the cooling operation and becomes an intermediate opening degree between a full closed state and a full open state (not shown).

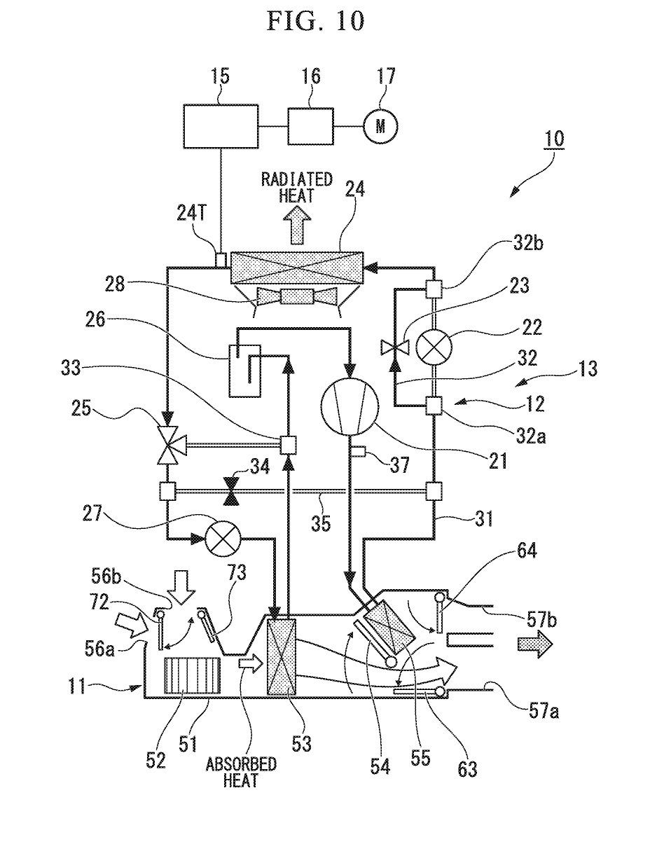

Next, an example of increasing the electric power consumption of the vehicle air conditioner 10 by decreasing the target temperature of the first indoor heat exchanger 53 of the vehicle air conditioner 10 and increasing the target temperature of the second indoor heat exchanger 55 will be described with reference to FIG. 10 as the fifth waste electric power control.

(Fifth Waste Electric Power Control)

As shown in FIG. 10, when the remaining capacity of the power storage device 16 is equal to or larger than a predetermined value, the control device 15 controls the target temperature of the first indoor heat exchanger 53 to be smaller than that of a case in which the remaining capacity of the power storage device is smaller than the predetermined value along with the operation of the compressor 21. At the same time, the control device 15 controls the target temperature of the second indoor heat exchanger 55 to be larger than that of a case in which the remaining capacity of the power storage device is smaller than the predetermined value.

In this way, when the target temperature of the first indoor heat exchanger 53 decreases, the cooling work of the vehicle air conditioner 10 can be increased. Further, when the target temperature of the second indoor heat exchanger 55 increases, the heating work of the vehicle air conditioner 10 can be increased. Accordingly, it is possible to increase the electric power consumption by decreasing the operation efficiency of the vehicle air conditioner 10.

Further, when the temperature of the air is decreased by the first indoor heat exchanger 53 and the low-temperature air is heated again by the second indoor heat exchanger 55, it is possible to obtain the cooling capacity before the waste electric power control.

In a state in which the cooling capacity before the waste electric power control is obtained, the electric power consumption of the vehicle air conditioner 10 can be increased. Accordingly, in the fifth waste electric power control, it is possible to prevent the overcharging of the power storage device 16 when the electric power consumption of the compressor 21 is larger than the electric power generated by the electric motor 17. Further, it is possible to decrease an increase speed of the remaining capacity of the power storage device 16 when the electric power consumption of the compressor 21 is smaller than the electric power generated by the electric motor 17.

Furthermore, the fifth waste electric power control may be not only the cooling operation but also the dehumidifying cooling operation. In the case of the dehumidifying cooling operation, the opening degree of the air mix damper 54 is larger than that of the cooling operation and becomes an intermediate opening degree between a full open state and a full closed state (not shown).

Here, for example, when the heating amount of the second indoor heat exchanger 55 is too large, the air mix damper 54 is moved in a closing direction so that the cooling capacity before the waste electric power control can be obtained.

Meanwhile, when the cooling amount of the first indoor heat exchanger 53 is too large, the air mix damper 54 is moved in an opening direction so that the cooling capacity before the waste electric power control can be obtained.

Further, when a decrease in temperature of the first indoor heat exchanger 53 is adjusted, the electric power consumption increase amount can be adjusted.

Furthermore, when a target temperature of blown air is equal to or smaller than a predetermined value at the time of performing the dehumidifying heating operation shown in FIG. 4 or the heating operation shown in FIG. 2, the dehumidifying cooling operation of the first to fifth waste electric power control can be selected. Since the predetermined value of the blown air is set for each of the external air temperature and the blower voltage, the accuracy is improved and hence the predetermined value can be set in the wider target blown air temperature range.

Next, the waste electric power control of the vehicle air conditioner 10 in the dehumidifying heating operation mode will be described. When the waste electric power control in the dehumidifying heating operation mode shown in FIG. 4 is performed, the cooling operation mode is selected and the first to fifth waste electric power control shown in FIGS. 5 to 10 described in the cooling operation mode is performed.

In this way, when the waste electric power control is performed in the cooling operation mode, the dehumidifying operation (the dehumidifying cooling operation and the dehumidifying cooling operation) mode, or the like, the efficiency of the cooling cycle of the vehicle air conditioner 10 is decreased and hence the electric power consumption of the vehicle air conditioner 10 is increased. Accordingly, it is possible to prevent the overcharging of the power storage device 16 when the electric power consumption of the compressor 21 is larger than the electric power generated by the electric motor 17. Further, it is possible to decrease an increase speed of the remaining capacity of the power storage device 16 when the electric power consumption of the compressor 21 is smaller than the electric power generated by the electric motor 17.

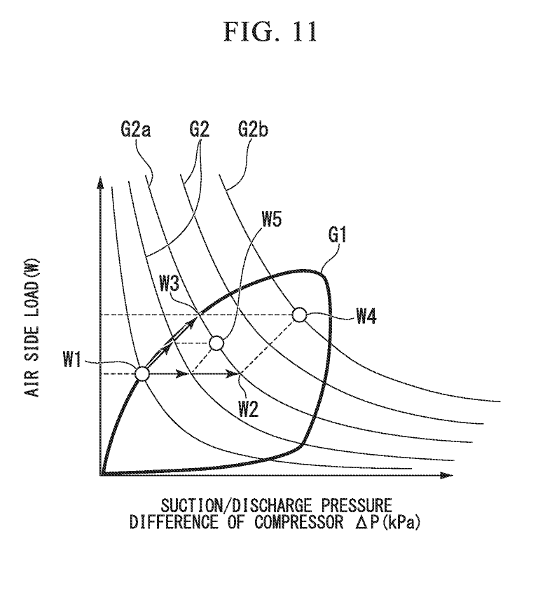

Next, an example of performing a combination of the first to fifth waste electric power control in response to an increase amount (waste electric power amount) of the electric power consumption required to prevent the overcharging of the power storage device 16 will be described with reference to FIG. 11, Table 1, and Table 2.

FIG. 11 shows a relationship of the electric power consumption with respect to the air side load (air conditioning load) and the suction/discharge pressure difference of the compressor 21. In FIG. 11, a vertical axis indicates the air side load (W) and a horizontal axis indicates the suction/discharge pressure difference ΔP (kPa) of the compressor 21. Further, the cooling operation range is indicated by a line diagram G1 and the electric power consumption is indicated by an iso-electric power line G2.

In the iso-electric power line G2, an iso-electric power line G2a indicates target electric power consumption (that is, a target waste electric power amount) and an iso-electric power line G2b indicates maximum electric power consumption (that is, a maximum waste electric power amount).

It is possible to appropriately combine the first to fifth waste electric power control in response to the electric power increase amount (the waste electric power amount) required for preventing the overcharging of the power storage device 16 by recognizing the characteristic of the line diagram of FIG. 11. When combining the first to fifth waste electric power control, it is desirable to consider the control performance of the waste electric power amount in the first to fifth waste electric power control.

Here, when the electric power consumption shown in the line diagram of FIG. 11 is set for each of the evaporation temperature of the first indoor heat exchanger 53, the discharge pressure of the compressor 21, and the suction pressure of the compressor 21, it is possible to further improve the accuracy when combining the first to fifth waste electric power control.

When there is a plurality of combinations of the first to fifth waste electric power control, it is desirable to determine and select the priority rank of the waste electric power control on the basis of the limitation conditions such as the first to fifth conditions.

A first condition indicates the waste electric power control which prioritizes the responsiveness when increasing the electric power consumption.

A second condition indicates the waste electric power control which prioritizes the durability.

A third condition indicates the waste electric power control which prioritizes an influence on noise/vibration (NV).

A fourth condition indicates the waste electric power control which prioritizes an AC temperature change.

A fifth condition indicates the waste electric power control which prioritizes AC discomfort.

The “AC temperature change” indicates a change in breath temperature and a continuous change. The “AC discomfort” means odor derived from the vehicle air conditioner 10, a difference in discharge air temperature between the outlets, a change in air volume, and the like other than a change in temperature.

For example, the priority determination and the rank of the first to fifth conditions are set as follows.

That is, the priority rank of the first to fifth conditions is determined by which priority condition is satisfied at each time. In particular, when a condition to be prioritized is not satisfied or when a plurality of conditions to be prioritized are satisfied, it is judged according to the priority rank of “A to E” set in Table 1 in advance.

The “prioritized condition” is shown in Table 1.

TABLE 1

| Request and | | Priority |
|---|---|---|
| limitation condition | Required condition | rank |
| First condition | When it is required to adjust waste electric power amount and to start | A |
| (responsiveness) | and stop waste electric power of predetermined responsiveness or more | |
| | in accordance with traveling state, SOC level, vehicle speed, gradient, | |
| | brake stepping force, and handle steering angle are determined | |
| Second condition | Case in which prevention of function loss due to failure at | B |
| (durability influence) | predetermined traveling distance/use time or less is prioritized even | |
| | when performance is ensured by waste electric power due to total | |
| | operation time or total workload of compressor exceeding | |
| | predetermined value in accordance with heavy use | |
| Third condition (NV | Case in which battery SOC is lowered by waste electric power in | C |
| influence) | preparation of downhill when vehicle speed is slow or vehicle is | |
| | stopped | |
| Fourth condition (ac | Case in which difference between indoor temperature and target indoor | D |
| temperature change) | temperature is large and gap with respect to target blow air temperature | |
| | needs to be minimized or case in which difference between indoor | |
| | temperature and target indoor temperature is small and change in | |
| | blown air temperature is noticeable | |
| Fifth condition (ac | Case in which external air humidity is high and change in odor or | E |
| discomfort) | humidity of blown air in accordance with dehumidification is large or | |
| | case in which outlet is provided at two or more positions and | |
| | difference of blown air temperature due to dehumidification changes | |

That is, when it is desired to promptly cope with an increase in electric power consumption at the time of suppressing the overcharging of the power storage device 16, the waste electric power control of the first condition is selected in consideration of the “prioritized condition” of Table 1. Further, when it is desired to suppress an influence on the durability of the vehicle air conditioner 10 at the time of preventing the overcharging of the power storage device 16, the waste electric power control of the second condition is selected in consideration of the “prioritized condition” of Table 1. Furthermore, when it is desired to suppress an influence on the noise/vibration (hereinafter, referred to as NV) of the vehicle air conditioner 10 (that is, the electric vehicle Ve) at the time of preventing the overcharging of the power storage device 16, the waste electric power control of the third condition is selected in consideration of the “prioritized condition” of Table 1.

Further, when it is desired to suppress an influence of a change in temperature of the cooling and dehumidifying operations by the vehicle air conditioner 10 at the time of preventing the overcharging of the power storage device 16, the waste electric power control of the fourth condition is selected in consideration of the “prioritized condition” of Table 1. Furthermore, when it is desired to suppress an influence of the discomfort of the cooling and dehumidifying operations by the vehicle air conditioner 10 at the time of preventing the overcharging of the power storage device 16, the waste electric power control of the fifth condition is selected in consideration of the “prioritized condition” of Table 1.

Here, the selection of the first to fifth waste electric power control also includes a combination of the waste electric power control and the waste electric power control is desirably selected to match a necessary waste electric power amount in response to the electric power consumption characteristic for the air side load (the air conditioning load) and the suction/discharge pressure difference of the compressor 21 shown in the line diagram of FIG. 11.

For example, it is possible to increase the electric power consumption W2 after the waste electric power control from the electric power consumption W1 before the waste electric power control to the target waste electric power amount by performing the first to third waste electric power control among the first to fifth waste electric power control. Further, it is possible to increase the electric power consumption W3 after the waste electric power control from the electric power consumption W1 before the waste electric power control to the target waste electric power amount by performing the fourth and fifth waste electric power control.

Furthermore, it is possible to increase the electric power consumption W4 after the waste electric power control from the electric power consumption W1 before the waste electric power control to the maximum waste electric power amount by performing the first to fifth waste electric power control.

Further, it is possible to increase the electric power consumption W5 after the waste electric power control from the electric power consumption W1 before the waste electric power control to the target waste electric power amount by performing the waste electric power control selected from the first to third waste electric power control and performing the waste electric power control selected from the fourth and fifth waste electric power control.

Next, an example of selecting a preferable waste electric power control from the first to fifth waste electric power control so as to satisfy each condition of the first condition to the fifth condition will be described with reference to Table 2. As the performance level selecting the waste electric power control, “Aa” to “Ae”, “Ba” to “Be”, “Ca” to “Ce”, “Da” to “De”, and “Ea” to “Ee” are shown in Table 2.

The order of the good order of “Aa” to “Ae”, “Ba” to “Be”, “Ca” to “Ce”, “Da” to “De”, and “Ea” to “Ee” shown in Table 2 changes in accordance with the specification of the vehicle. For example, when the first condition is performed, the waste electric power control is performed from the control having the smallest electric power consumption in the first condition.

As an example, when the electric power consumption amount has a relationship of Aa<Ab<Ac<Ad<Ae, the waste electric power control is sequentially performed from “Aa” having a small electric power consumption amount.

Here, the waste electric power control which can be performed is different in accordance with the state of the vehicle. For example, there is a case in which the waste electric power control of “Ac” and “Ae” cannot be performed even when the electric power consumption amount satisfies a relationship of Aa<Ab<Ac<Ad<Ae at the time of performing the waste electric power control in the first condition. In this case, the waste electric power control having a small electric power consumption amount among “Aa”, “Ab”, and “Ad” is sequentially selected and performed.

Hereinafter, a priority rank of selecting a preferable waste electric power control from the first to fifth waste electric power control so as to satisfy each condition of the first condition to the fifth condition will be described with reference to Table 2.

TABLE 2

| | | | Second | | Fourth | |
|---|---|---|---|---|---|---|
| | | First waste | waste | | waste | Fifth waste |
| | | electric | electric | Third waste | electric | electric |
| | | power | power | electric | power | power |
| Request and limitation condition | | control | control | power control | control | control |
| First condition | Good = fast | Aa | Ab | Ac | Ad | Ae |
| (responsiveness) | | | | | | |
| Second | Good = little | Ba | Bb | Bc | Bd | Be |
| condition | influence | | | | | |
| (durability | | | | | | |
| influence) | | | | | | |
| Third condition | Good = little | Ca | Cb | Cc | Cd | Ce |
| (NV influence) | influence | | | | | |
| Fourth | Good = little | Da | Db | Dc | Dd | De |
| condition (ac | change | | | | | |
| temperature | | | | | | |
| change) | | | | | | |
| Fifth condition | Good = little | Ea | Eb | Ec | Ed | Ee |
| (ac discomfort) | discomfort | | | | | |

First, an example of performing the waste electric power control in consideration of the first condition will be described with reference to Table 2.

For example, when it is desired to ensure the electric power consumption having most excellent responsiveness in a case in which the electric power consumption amount of the performance level of the first condition satisfies a relationship of Aa<Ab<Ac<Ad<Ae and the waste electric power control of “Aa” to “Ae” can be performed, the first waste electric power control with the number of “Aa” is selected. When it is desired to ensure an excellent electric power consumption after the first waste electric power control, the second waste electric power control with the number of “Ab” is selected. When it is desired to ensure an excellent electric power consumption after the second waste electric power control, the third waste electric power control with the number of “Ac” is selected. When it is desired to ensure an excellent electric power consumption after the third waste electric power control, the fourth waste electric power control with the number of “Ad” is selected. When it is desired to ensure an excellent electric power consumption after the fourth waste electric power control, the fifth waste electric power control with the number of “Ae” is selected.

Next, an example of performing the waste electric power control in consideration of the second condition will be described. For example, when it is desired to minimize the durability in a case in which the electric power consumption amount of the performance level of the second condition satisfies a relationship of Ba<Bb<Bc<Bd<Be and the waste electric power control of “Ba” to “Be” can be performed, the first waste electric power control with the number of “B a” is selected. When it is desired to reduce an influence on the durability after the first waste electric power control, the second waste electric power control with the number of “Bb” is selected. When it is desired to reduce an influence on the durability after the second waste electric power control, the third waste electric power control with the number of “Bc” is selected. When it is desired to reduce an influence on the durability after the third waste electric power control, the fourth waste electric power control with the number of “Bd” is selected. When it is desired to reduce an influence on the durability after the fourth waste electric power control, the fifth waste electric power control with the number of “Be” is selected.

Next, an example of performing the waste electric power control in consideration of the third condition will be described. For example, when it is desired to minimize an influence on NV in a case in which the electric power consumption amount of the performance level of the third condition satisfies a relationship of Ca<Cb<Cc<Cd<Ce and the waste electric power control of “Ca” to “Ce” can be performed, the first waste electric power control with the number of “Ca” is selected. When it is desired to reduce an influence on NV after the first waste electric power control, the second waste electric power control with the number of “Cb” is selected. When it is desired to reduce an influence on NV after the second waste electric power control, the third waste electric power control with the number of “Cc” is selected. When it is desired to reduce an influence on NV after the third waste electric power control, the fourth waste electric power control with the number of “Cd” is selected. When it is desired to reduce an influence on NV after the fourth waste electric power control, the fifth waste electric power control with the number of “Ce” is selected.

Next, an example of performing the waste electric power control in consideration of the fourth condition will be described. For example, when it is desired to minimize a temperature change in a case in which the electric power consumption amount of the performance level of the fourth condition satisfies a relationship of Da<Db<Dc<Dd<De and the waste electric power control of “Da” to “De” can be performed, the first waste electric power control with the number of “Da” is selected. When it is desired to reduce a change in temperature after the first waste electric power control, the second waste electric power control with the number of “Db” is selected. When it is desired to reduce a change in temperature after the second waste electric power control, the third waste electric power control with the number of “Dc” is selected. When it is desired to reduce a change in temperature after the third waste electric power control, the fourth waste electric power control with the number of “Dd” is selected. When it is desired to reduce a change in temperature after the fourth waste electric power control, the fifth waste electric power control with the number of “De” is selected.

Next, an example of performing the waste electric power control in consideration of the fifth condition will be described. For example, when it is desired to minimize the discomfort in a case in which the electric power consumption amount of the performance level of the fifth condition satisfies a relationship of Ea<Eb<Ec<Ed<Ee and the waste electric power control of “Ea” to “Ee” can be performed, the first waste electric power control with the number of “Ea” is selected. When it is desired to reduce the discomfort after the first waste electric power control, the second waste electric power control with the number of “Eb” is selected. When it is desired to reduce the discomfort after the second waste electric power control, the third waste electric power control with the number of “Ec” is selected.

When it is desired to reduce the discomfort after the third waste electric power control, the fourth waste electric power control with the number of “Ed” is selected. When it is desired to reduce the discomfort after the fourth waste electric power control, the fifth waste electric power control with the number of “Ee” is selected.

In this way, when the first to fifth waste electric power control is selected in consideration of the first condition to the fifth condition shown in Table 2, it is possible to perform the waste electric power control satisfying each condition.

Furthermore, the technical scope of the present invention is not limited to the above-described embodiment and can be modified into various forms without departing from the spirit of the present invention.

For example, in the above-described embodiment, an electric vehicle has been exemplified as a battery electric vehicle, but the present invention is not limited thereto.

The present invention may be applied to, for example, a hybrid vehicle and a fuel cell vehicle as other vehicles.

What is claimed is:

1. An electric vehicle including an electric motor, a power storage device electrically connected to the electric motor, and a control device controlling the electric motor and the power storage device, comprising:
a refrigerant circuit which includes a compressor compressing and discharging a sucked refrigerant, an outdoor heat exchanger exchanging heat with the compressed refrigerant, an expansion valve decompressing the refrigerant passing through the outdoor heat exchanger, and an indoor heat exchanger exchanging heat with the decompressed refrigerant and returning the refrigerant to the compressor,
wherein the refrigerant circuit includes a resistance which is provided between the compressor and the outdoor heat exchanger to change a passage resistance of the compressed refrigerant, and
wherein, when a remaining capacity of the power storage device is equal to or larger than a predetermined value, the control device increases the passage resistance as compared with a case in which the remaining capacity of the power storage device is smaller than the predetermined value along with the operation of the compressor.

2. An electric vehicle including an electric motor, a power storage device electrically connected to the electric motor, and a control device controlling the electric motor and the power storage device, comprising:
a refrigerant circuit which includes a compressor compressing and discharging a sucked refrigerant, an outdoor heat exchanger exchanging heat with the compressed refrigerant, an expansion valve decompressing the refrigerant passing through the outdoor heat exchanger, and an indoor heat exchanger exchanging heat with the decompressed refrigerant and returning the refrigerant to the compressor,
wherein, when a remaining capacity of the power storage device is equal to or larger than a predetermined value, the control device decreases a passing air volume of a first air guide member controlling the passing air volume of the outdoor heat exchanger as compared with a case in which the remaining capacity of the power storage device is smaller than the predetermined value along with the operation of the compressor.

3. An electric vehicle including an electric motor, a power storage device electrically connected to the electric motor, and a control device controlling the electric motor and the power storage device, comprising:
a refrigerant circuit which includes a compressor compressing and discharging a sucked refrigerant, an outdoor heat exchanger exchanging heat with the compressed refrigerant, an expansion valve decompressing the refrigerant passing through the outdoor heat exchanger, and an indoor heat exchanger exchanging heat with the decompressed refrigerant and returning the refrigerant to the compressor,
wherein, when a remaining capacity of the power storage device is equal to or larger than a predetermined value, the control device decreases an opening degree of the expansion valve as compared with a case in which the remaining capacity of the power storage device is smaller than the predetermined value along with the operation of the compressor.

4. An electric vehicle including an electric motor, a power storage device electrically connected to the electric motor, and a control device controlling the electric motor and the power storage device, comprising:
a refrigerant circuit which includes a compressor compressing and discharging a sucked refrigerant, an outdoor heat exchanger exchanging heat with the compressed refrigerant, an expansion valve decompressing the refrigerant passing through the outdoor heat exchanger, and an indoor heat exchanger exchanging heat with the decompressed refrigerant and returning the refrigerant to the compressor,
wherein the refrigerant circuit includes a second indoor heat exchanger which is disposed between the compressor and the outdoor heat exchanger to exchange heat with the compressed refrigerant, and
wherein, when a remaining capacity of the power storage device is equal to or larger than a predetermined value, the control device decreases a target temperature of the indoor heat exchanger as compared with a case in which the remaining capacity of the power storage device is smaller than the predetermined value and increases a target temperature of the second indoor heat exchanger as compared with the case in which the remaining capacity of the power storage device is smaller than the predetermined value along with the operation of the compressor.

5. The electric vehicle according to claim 1, further comprising:
a switching member that is provided in the indoor heat exchanger to switch an introduction of air inside a vehicle compartment of the electric vehicle and air outside the vehicle compartment,
wherein, when the remaining capacity of the power storage device is equal to or larger than the predetermined value, the control device switches the switching member to introduce the air outside the vehicle compartment.

6. The electric vehicle according to claim 2, further comprising:
a switching member that is provided in the indoor heat exchanger to switch an introduction of air inside a vehicle compartment of the electric vehicle and air outside the vehicle compartment,
wherein, when the remaining capacity of the power storage device is equal to or larger than the predetermined value, the control device switches the switching member to introduce the air outside the vehicle compartment.

7. The electric vehicle according to claim 3, further comprising:
a switching member that is provided in the indoor heat exchanger to switch an introduction of air inside a vehicle compartment of the electric vehicle and air outside the vehicle compartment,
wherein, when the remaining capacity of the power storage device is equal to or larger than the predetermined value, the control device switches the switching member to introduce the air outside the vehicle compartment.

8. The electric vehicle according to claim 4, further comprising:
a switching member that is provided in the indoor heat exchanger to switch an introduction of air inside a vehicle compartment of the electric vehicle and air outside the vehicle compartment,
wherein, when the remaining capacity of the power storage device is equal to or larger than the predetermined value, the control device switches the switching member to introduce the air outside the vehicle compartment.
